(19) United States
(12) Patent Application Publication
(10) Pub. No.: US 2005/0156186 A1
(43) Pub. Date: Jul. 21, 2005

(54) Light-emitting diode with prevention of electrostatic damage

(76) Inventors: Ming-Der Lin, Hsinchu (TW); San Bao Lin, Jungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/019,175

(22) Filed: Dec. 23, 2004

(30) Foreign Application Priority Data
Jan. 20, 2004 (TW) 093101499

(51) Int. Cl. H01L 29/22

(52) U.S. Cl. 257/99

(57) ABSTRACT

A light-emitting diode (LED) device with prevention of electrostatic damage, mainly comprises a surface insulated substrate onto which at least one power supply circuit and at least one second power supply circuit are provided, the former being electrically connected to a LED first electrode of a LED and a ESD second electrode of an electrostatic discharge protection device, while the latter being electrically connected to a LED second electrode of the LED and a ESD first electrode of the electrostatic discharge protection device, in such a way that an inverse-parallel circuit is formed by the LED and the electrostatic discharge protection device. Thus, not only a simplified manufacturing process and raised yield rate, but also a prolonged service life of the LED device may be obtained, due to the feature that active areas of the first power supply circuit and second power supply circuit are larger than those of the ESD first electrode and ESD second electrode.

### FIELD OF THE INVENTION

The present invention is related to a light-emitting diode device, particularly to a light-emitting diode device with prevention of electrostatic damage, facilitating not only a simplified manufacturing process and raised yield rate, but also a prolonged service life of the light-emitting diode device.

### BACKGROUND

Light-emitting diodes (LEDs) have been widely used in computer peripherals, communication products, and other electronic equipments owing to advantages, such as small volume, light weight, lower power consumption, and long service life, as examples. Whether in the manufacturing process or in use, it is common for the LED to be damaged owing to an electrostatic discharge effect. Therefore, how to avoid misgivings about the damage to the LED resulted from this electrostatic discharge effect is the major key point in the design and manufacture of the LED device.

Referring FIG. 1, there is shown a circuit diagram of a conventional LED device with an electrostatic discharge protective effect, the main construction thereof comprising a LED 10 and a zener diode 30 connected in inverse parallel, as illustrated in this figure. For the LED 10, when a normal input voltage Vcc is supplied, forward bias between two ends thereof is naturally formed, thus facilitating the current to flow therethrough and further enabling the LED 10 to project a light source; meanwhile, for the zener diode 20, reverse bias between two ends thereof is formed such that a disconnected condition without any electrical power consumption is presented. If the electrostatic discharge phenomenon occurs, an abnormal large input voltage Vcc is formed between two sides of the zener diode 20 to make this zener diode 20 break down. Once the zener diode 20 breaks down, it should be formed as a short circuit, such that a majority of current flows therethrough, instead of through the LED 10. Thereby, the damage to the LED 10 may be avoided. Moreover, if the value of the input voltage Vcc is negative, the zener diode 20 may conduct due to forward bias, while the LED 10 may not conduct owing to reverse bias.

Subsequently, referring to FIG. 2, there is shown a structural diagram of the conventional LED device with electrostatic discharge protection. As illustrated in this figure, the main construction is characterized in that a LED second electrode 19 (for instance, P-electrode or N-electrode) and a LED first electrode 17 (for instance, N-electrode or P-electrode) of the LED 10 are electrically connected to a ZD first electrode 27 and a ZD second electrode 29 of the zener diode 20, respectively, such that a state of inverse-parallel connection is formed between the LED 10 and the zener diode 20.

In this case, the LED 10 comprises a die substrate 11, a first epitaxial layer 13 grown on top of the die substrate 11, and a second epitaxial layer 15 grown on top of a part of the first epitaxial layer 13. The LED second electrode 19 is fixedly provided on the top surface of the second epitaxial layer 15, while the LED first electrode 17 is fixedly provided on the top surface of the first epitaxial layer 13. In addition, the zener diode 20 includes a second doped region 25, a first doped region 23, a ZD second electrode 29 connected to the second doped region 25, and a ZD first electrode 27 connected to the first doped region 23. Further, the first doped region 23 is additionally provided with a first exterior electrode 21 thereon, and only the power supply between the first exterior electrode 21 and the second electrode 29 of this zener diode (i.e., second exterior electrode) is required for operation.

Although the function of preventing the LED 10 from being damaged by electrostatic discharge is provided in the above conventional LED device, this LED 10 must be inverted and then fixed on the zener diode 20 in a manufacturing process, which requires a precision alignment equipment, thus not only expending cost, but also increasing manufacturing difficulty correspondingly. Moreover, with this design, in which the zener diode 20 is used as a sub mount of the LED 10, a great deal of material and manufacturing cost may be wasted owing to the considerable bulkness of this zener diode 20.

### SUMMARY OF THE INVENTION

For this purpose, how to design a novel light-emitting diode (LED) device which, aiming at disadvantages of above conventional art, may not only prevent the LED from being damaged by electrostatic discharge, but also simplify the manufacturing process and reduce the manufacturing cost, is the key point of the present invention.

Accordingly, it is the primary object of the present invention to provide a LED device with prevention of electrostatic damage, in which a LED and an electrostatic discharge protection device is allowed to be fixedly provided on a first power supply circuit and a second power supply circuit, respectively, of a surface insulated substrate directly, resulting in not only an electrostatic discharge prevention effect, but also a simplified manufacturing process and raised yield rate of product.

It is the secondary object of the present invention to provide a LED device with prevention of electrostatic damage enabling the extended patterns and application fields of the LED by the use of different electrostatic discharge protection devices in cooperation with operation voltages of LEDs having different color lights.

It is another object of the present invention to provide a LED device with prevention of electrostatic damage capable of achieving an equivalent electrostatic discharge protective effect with reduced manufacturing cost by means of a smaller electrostatic discharge protection device.

It is still another object of the present invention to provide a LED device with prevention of electrostatic damage having a substrate selectively formed from insulating material with a coefficient of thermal expansion approaching to that of a LED, in order to prevent the LED from coming off the insulating substrate, further leading to a prolonged service life of product.

For the purpose of achieving aforementioned objects, the present invention provides a LED device with prevention of electrostatic damage, the main construction thereof comprising a surface insulated substrate on which at least one first power supply circuit and at least one second power supply circuit are provided; at least one LED including a LED first electrode and a LED second electrode, the former being electrically connected to the first power supply circuit of the surface insulated substrate, while the latter being electrically connected to the second power supply circuit thereof; and an electrostatic discharge protection device including a ESD first electrode and a ESD second electrode, in which the former is electrically connected to the second power supply circuit of the surface insulated substrate , while the latter is electrically connected to the first power supply circuit thereof, resulting in an inverse-parallel connection formed by the electrostatic discharge protection device and the LED.

### BRIEF DESCRIPTION OF DRAWINGS

FIG. 1 is a circuit diagram of a conventional light-emitting diode (LED) device with electrostatic protective effect;

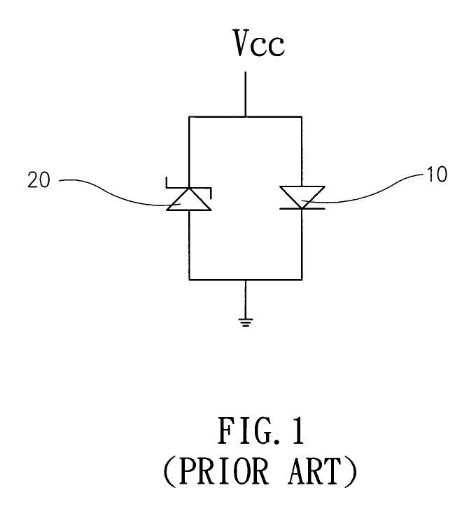

FIG. 2 is a structural diagram of the above conventional LED device with electrostatic protective effect;

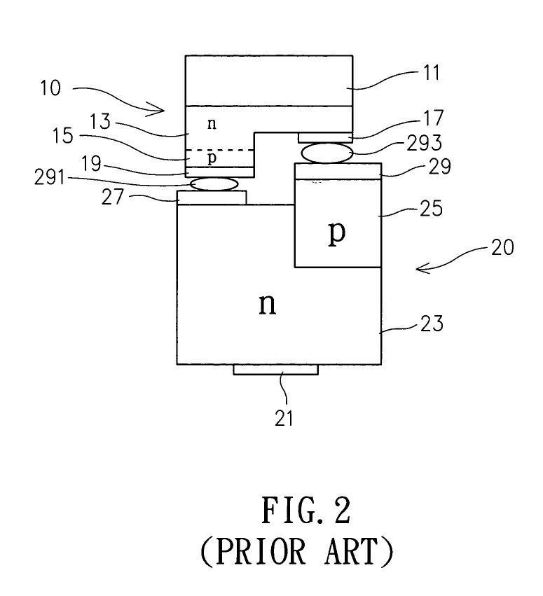

FIGS. 3A and 3B are a structural disassembled diagram and an assembled diagram according to one preferred embodiment of the present invention;

FIGS. 4A and 4B are a top view and a circuit diagram, respectively, according to another embodiment of the present invention;

FIG. 5 is a structural side view according to another embodiment of the present invention;

FIG. 6 is a structural top view according to still another embodiment of the present invention;

FIGS. 7A and 7B are a structural side view and a top view, respectively, according to yet another embodiment of the present invention; and

FIGS. 8A and 8B are a circuit diagram and a structural top view according to yet still another embodiment of the present invention.

### DETAILED DESCRIPTION

The structural features and the effects to be achieved may further be understood and appreciated by reference to the presently preferred embodiments together with the detailed description.

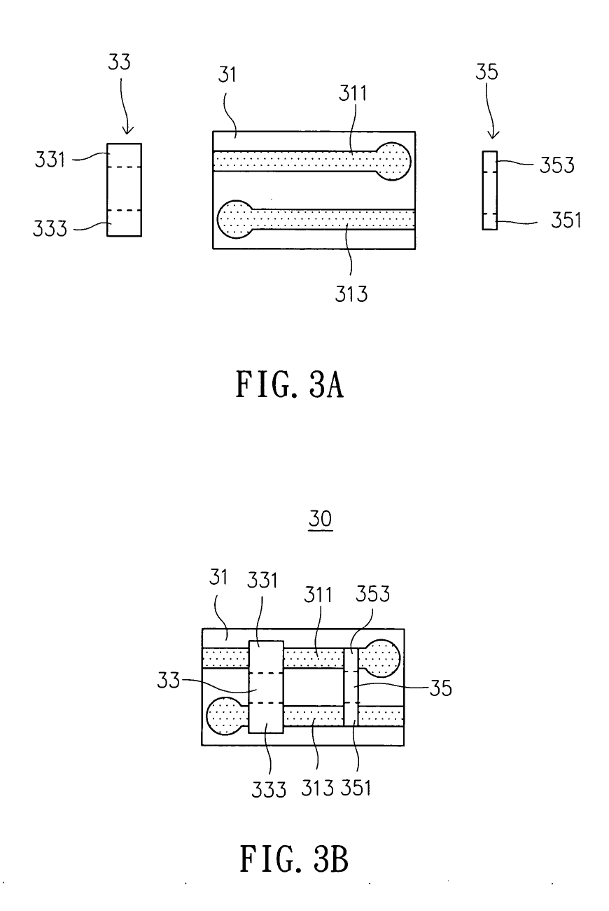

Referring to FIGS. 3A and 3B, firstly, there are shown a structural exploded diagram according to one preferred embodiment of the present invention and an assembled diagram thereof, respectively. A light-emitting diode (LED) device 30 with prevention of electrostatic damage of the present invention is formed mainly by inverting a LED 33 and an electrostatic discharge protection device 35 in the manner of flip chip, followed by adhering them having being inverted in the manner of flip chip onto a surface insulated substrate 31 having at least one first power supply circuit 311 and at least one second power supply circuit 313.

In this case, the LED 33, such as a flat LED illustrated in this embodiment, may comprise a LED second electrode 333 and a LED first electrode 331; while the electrostatic discharge protection device 35 may also comprise an ESD second electrode 353 and an ESD first electrode 351. The LED second electrode 333 may be electrically connected to the second power supply circuit 313, while the LED first electrode 331 may be electrically connected to the first power supply circuit 311, when the LED 33 is adhered on the surface insulated substrate 31. For the electrostatic discharge protection device 35, on the contrary, the ESD first electrode 351 may be electrically connected to the second power supply circuit 313, while the ESD second electrode 353 may be electrically connected to the first power supply circuit 311. In this case, an inverse-parallel connection is formed by the LED 33 and electrostatic discharge protection device 35. Eutectic bonding or soldering formed by adhesive material, such as AuSi, AuSn, PbSn, SnAg, and SnInAg, as examples, may be served as the way for electrical connection. Due to the high coefficient of thermal conductivity, except for good adhesive property, inherent to the AuSn, PbSn, SnAg, and SnInAg used in the eutectic bonding or soldering, the high temperature generated from the LED 33 may be transmitted out rapidly via the surface insulated substrate 31, such that the normal operation temperature of the LED 33 may be maintained. Thereby, the luminous efficiency may be raised. Meanwhile, benefiting from the resistance to high temperature (over 200° C.), such an adhesive material extremely facilitates a subsequent manufacturing process of adhering the surface insulated substrate 31 onto a heat sink.

Further, not only the manufacturing difficulty in electrical connection among the LED first electrode 331, LED second electrode 333, ESD first electrode 351, and ESD second electrode 353 may be effectively reduced, but also the yield rate of product may be relatively raised, due to the fact that active areas of the first power supply circuit 311 and the second power supply circuit 313 are much larger those of a ZD first electrode (27) and a ZD second electrode (29) of a ZD 20, leading to a wider allowance when the electrodes are adhered together.

Furthermore, based on the material of the LED 33, an electrically insulated material, such as Si₃N₄, Al₂O₃, AlN, BeO, as well as SiC, Si, GaN covered with the dielectric material (SiO₂, TiO₂, Si₃N₄, and so forth), as examples, having superior thermal conductivity and a coefficient of thermal expansion similar to those of the LED 33 and electrostatic discharge protection device 35, may be selected as the surface insulated substrate 31 correspondingly, in order to avoid misgivings about the easy separation of the LED 33 from the surface insulated substrate 31, and thus ensure the electrostatic protective function while increase the service life of product.

Moreover, the electrostatic discharge protection device 35 may be selected from a zener diode, Schottky barrier diode, silicon diode, group III-V element-based diode, electrostatic discharge protection integrated circuit, and other equivalent diodes, based on the principle including the setting of breakdown voltage concerning the electrostatic discharge protection for the LED, and further the cooperation between the coefficient of thermal expansion of the surface insulated substrate 31 and that of this device.

The volume, and then the cost of the electrostatic discharge protection device 35 may be reduced significantly with uniform function, owing to the adherence of the LED 33 and the electrostatic discharge protection device 35 onto the surface insulated substrate 31 in the present invention, unlike the design of direct adherence of the LED (10) onto the zener diode (20) served as a base in the conventional art.

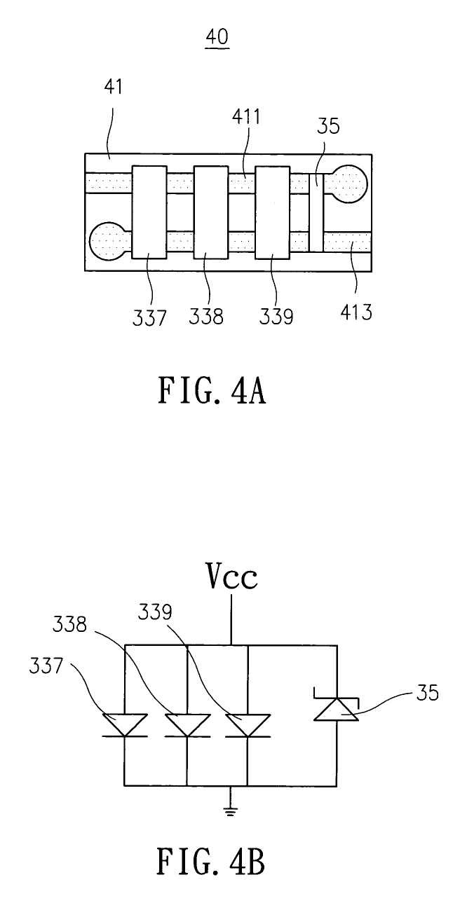

Moreover, referring to FIGS. 4A and 4B, there are shown a top view according to another embodiment of the present invention and a circuit diagram thereof, respectively. A LED device 40, as shown in these figures, comprises a plurality of LEDs 337, 338, 339, and an electrostatic discharge protection device 35 adhered, at two electrodes thereof, onto a first power supply circuit 411 and a second power supply circuit 413, respectively, of a surface insulated substrate 41 connected in parallel, in order to form a high power LED matrix. When the input voltage Vcc is a normal driving voltage, each of the LEDs 337, 338, and 339 are presented in a forward-biased state so as to generate a predetermined color light, while the electrostatic discharge protection device 35 is situated in a disconnected condition without electrical power consumption owing to reverse bias. On the contrary, if an abnormal large input voltage Vcc is inputted when electrostatic discharge occurs, the electrostatic discharge protection device 35 may conduct under breakdown state, such that a majority of current may flow through the electrostatic discharge protection device 35. Further, when the value of the input voltage Vcc is negative, the electrostatic discharge protection device 35 may be operated in a conducting state allowing the current to flow therethrough without damaging the LEDs 337, 338, 339 due to enormous bias voltage.

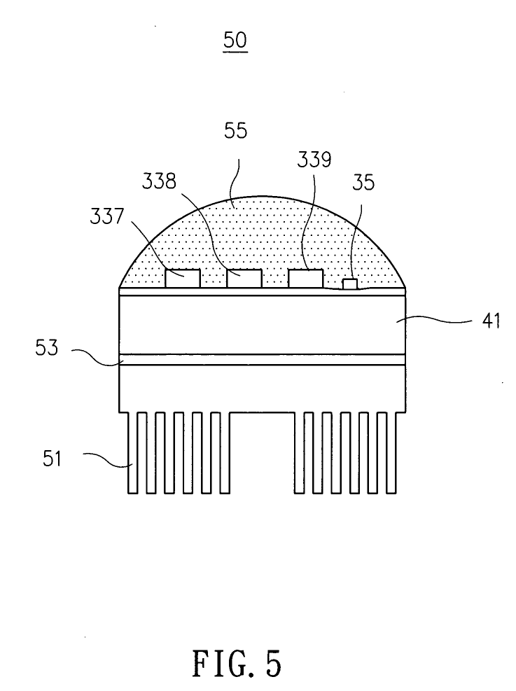

Referring to FIG. 5, further, there is shown a side diagram according to another embodiment of the present invention. As illustrated in this figure, a LED device 50 is connectedly provided with a heat sink 51 via a bonding layer 53 at the bottom of the surface insulated substrate 41 of the embodiment shown in FIG. 4, and covered with a protective adhesive 55 on the top of the surface insulated substrate 41, in which the material of the bonding layer 53 may be selected from AuSn, PbSn, SnAg, SnInAg, silver adhesive, and solder paste, etc. Thereby, the paths for quickly discharging the working heat source generated by the LEDs 337, 338, 339 may be increased, thus prolonging the service life and raising the luminous efficiency. In addition, with the protective adhesive 55, external hazard substance may be further isolated, and the probability of oxidizing damage to the LEDs 337, 338, 339 may be avoided correspondingly.

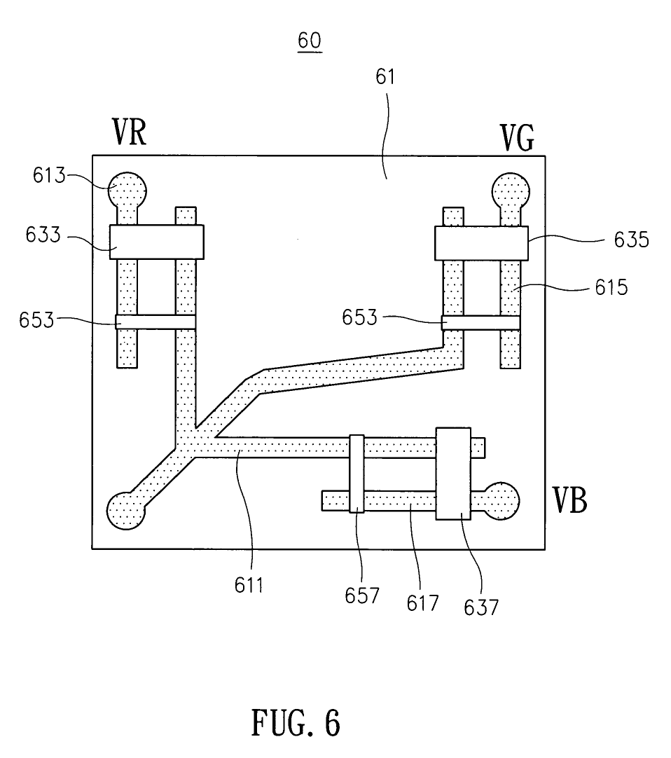

Moreover, referring to FIG. 6, there is shown a structural top diagram according to still another embodiment of the present invention. As shown in this figure, a LED device 60 is mainly provided with a common power supply circuit 611, a power supply circuit for red light 613, a power supply circuit for green light 615, and a power supply circuit for blue light 617, where the power supply circuit for red light 613, power supply circuit for green light 615, and power supply circuit for blue light 617 are fixedly provided with at least one LED for red light 633 and an electrostatic discharge protection device 653, at least one green LED 635 and an electrostatic discharge protection device 655, as well as at least one blue LED 637 and an electrostatic discharge protection device 657, respectively. As such, when red, green, and blue lights are mixed together, a white light source or full-color light source is then generated. Moreover, the electrostatic discharge protection devices 653, 655, 657 may be selected from diodes with different breakdown voltages, in order to cooperate with operation voltages of the red LED 633, green LED 635, and blue LED 637, whereby the best electrostatic protective effect may be obtained.

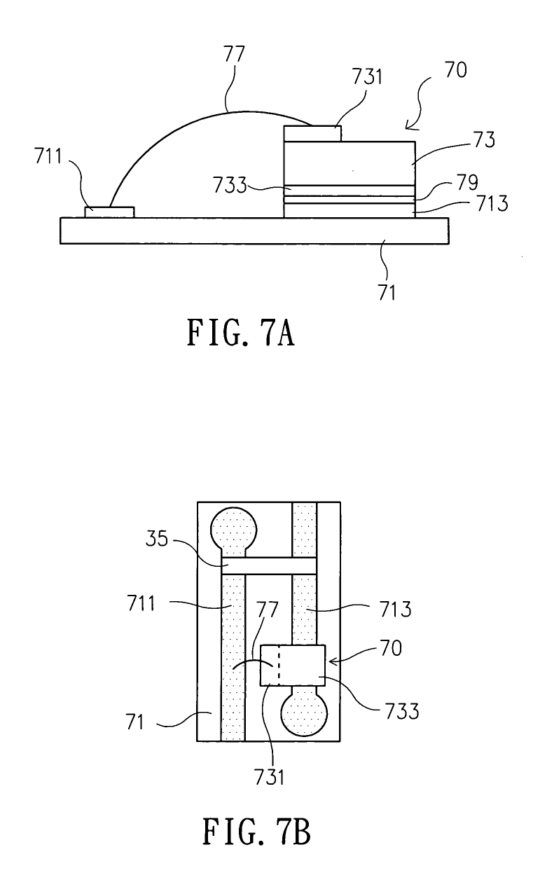

Furthermore, referring to FIGS. 7A and 7B, there are shown a side view and a top view, respectively, according to yet another embodiment of the present invention, mainly applied in an upright LED 70. As illustrated in these figures, the upright LED 70 comprises a LED first electrode 731 and a LED second electrode 733 provided on upper and lower sides of an epitaxial layer of LED 73, respectively. By means of a bonding layer 79, which is formed from the material, such as AuSn, PbSn, SnAg, SnInAg, silver adhesive, solder paste, AuSi, and so on, as examples, the LED second electrode 733 may be adhered onto the second power supply circuit 713 of a circuit board 71 directly. Moreover, a lead wire 77 is used to electrically connect the LED first electrode 731 with the first power supply circuit 711. Between the first power supply circuit 711 and the second power supply circuit 713, the electrostatic discharge protection device 35 is equally connected in order to ensure the electrostatic discharge protective function for the LED 70.

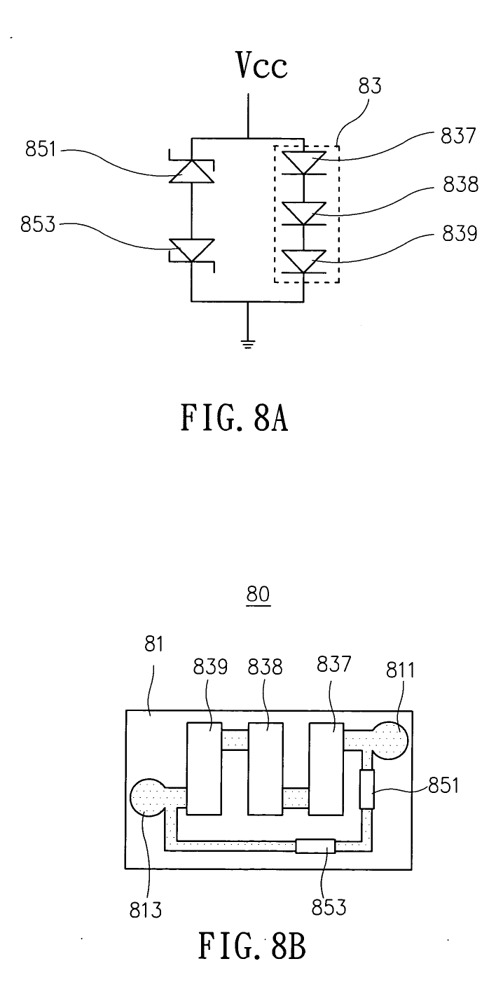

Finally, referring to FIGS. 8A and 8B, there are shown a circuit diagram according to yet still another embodiment of the present invention and a structural top view thereof, respectively. A LED device 80, as shown in these figures, mainly comprises a plurality of LEDs 837˜839 connected in series so as to form a LED set 83, where a first electrode of the LED 837 and a second electrode of another LED are fixed on a first power supply circuit 811 and a second power supply circuit 813, respectively, of a surface insulated substrate 81, as well as electrically connected in series between the first power supply circuit 811 and the second power supply circuit 813. Additionally, at least one pair of inversely connected Schottky barrier diodes 851, 853 are connected in series between the first power supply circuit 811 and the second power supply circuit 813, in such a way that the value of breakdown voltage may be increased. With this design of a plurality of LEDs connected in series, not only LED devices with different driving voltages may be established, but also different protection voltages may be further provided depending upon actual need by means of various arrangements of the electrostatic discharge protection device (Schottky barrier diode 85).

To sum up, it should be appreciated that the present invention is related to a light-emitting diode device, particularly to a light-emitting diode device with prevention of electrostatic damage, facilitating not only a simplified manufacturing process and raised yield rate, but also a prolonged service life of the light-emitting diode device.

The foregoing description is merely one embodiment of present invention and not considered as restrictive. All equivalent variations and modifications in process, method, feature, and spirit in accordance with the appended claims may be made without in any way from the scope of the invention.

### List of Reference Symbols

10 light-emitting diode
11 die substrate
13 first epitaxial layer
15 second epitaxial layer
17 LED first electrode
19 LED second electrode
20 zener diode
21 first exterior electrode
23 first doped region
25 second doped region
27 ZD first electrode
29 ZD second electrode
291 first tin ball
293 second tin ball
30 light-emitting diode device
31 surface insulated substrate
311 first power supply circuit
313 second power supply circuit
33 light-emitting diode
331 LED first electrode
333 LED second electrode
337 light-emitting diode
338 light-emitting diode
339 light-emitting diode
35 electrostatic discharge protection device
351 ESD first electrode
353 ESD second electrode
40 light-emitting diode device
41 surface insulated substrate
411 first power supply circuit
413 second power supply circuit
50 light-emitting diode device
51 heat sink
50 bonding layer
55 protective adhesive
60 light-emitting diode device
61 surface insulated substrate
611 common power supply circuit
613 power supply circuit for red light
615 power supply circuit for green light
617 power supply circuit for blue light
633 red light-emitting diode
635 green light-emitting diode
637 blue light-emitting diode
653 electrostatic discharge protection device
655 electrostatic discharge protection device
657 electrostatic discharge protection device
70 light-emitting diode
71 circuit board
711 first power supply circuit
713 second power supply circuit
73 epitaxial layer of light-emitting diode
731 LED first electrode
733 LED second electrode
77 lead wire
79 bonding layer
80 light-emitting diode device
81 surface insulated substrate
811 first power supply circuit
813 second power supply circuit
83 light-emitting diode set
837 light-emitting diode
838 light-emitting diode
839 light-emitting diode
851 Schottky barrier diode
853 Schottky barrier diode

1. A light-emitting diode (LED) device with prevention from electrostatic damage, comprising:
a surface insulated substrate on which at least one first power supply circuit and at least one second power supply circuit are provided;
at least one LED, each including a LED first electrode and a LED second electrode, the former being directly fixed to said first power supply circuit of said surface insulated substrate, while the latter being fixed to said second power supply circuit thereof; and
an electrostatic discharge protection device including a ESD first electrode and a ESD second electrode, wherein the former is also directly fixed to said second power supply circuit of said surface insulated substrate, while the latter is fixed to said first power supply circuit thereof, resulting in an inverse-parallel circuit formed by said electrostatic discharge protection device and said LED.

2. The LED device according to claim 1, wherein said surface insulated substrate is made from the material selected from the group consisting of Si₃N₄, Al₂O₃, AlN, BeO, as well as SiC, GaN, Si, covered with a dielectric material, and the combination thereof.

3. The LED device according to claim 2, wherein said dielectric material is selected from the group consisting of SiO₂, TiO₂, Si₃N₄, and the combination thereof.

4. The LED device according to claim 1, wherein said LED is adhered onto said surface insulated substrate in a manner of flip-chip package.

5. The LED device according to claim 4, wherein said LED first electrode and said LED second electrode of said LED are further electrically connected to said first power supply circuit and said second power supply circuit, respectively, by means of an adhesive material selected from the group consisting of AuSi, AuSn, PbSn, SnAg, SnInAg, silver adhesive, solder paste, and the combination thereof.

6. The LED device according to claim 1, wherein said electrostatic discharge protection device is selected from the group consisting of at least one zener diode, Schottky barrier diode, silicon diode, group III-V element-based diode, transistor, electrostatic discharge protection integrated circuit, and the combination thereof.

7. The LED device according to claim 1, wherein said LED is selected from the group consisting of a flat LED and an upright LED.

8. The LED device according to claim 7, wherein said LED first electrode and said LED second electrode of said LED are further electrically connected to said first power supply circuit and said second power supply circuit, respectively, by means of any one of a lead wire and a adhesive material.

9. The LED device according to claim 1, wherein said surface insulated substrate is further fixedly provided at the bottom thereof with a heat sink.

10. The LED device according to claim 1, wherein said LED is further provided at the top thereof with a protective adhesive.

11. The LED device according to claim 1, wherein said LED is selected from the group consisting of a red light-emitting, green LED, blue LED, and the combination thereof.

12. The LED device according to claim 11, wherein each of said LEDs is provided with a corresponding electrostatic discharge protection device, respectively.

13. The LED device according to claim 1, wherein a plurality of said LEDs are connected in series to be a light-emitting set, said LED first electrode of one of said LEDs being directly fixed to said first power supply circuit of said surface insulated substrate, while said LED second electrode of another one of said LEDs being directly fixed to said second power supply circuit of said surface insulated substrate.

14. The LED device according to claim 6, wherein said electrostatic discharge protection device is also formed by at least one pair of inversely connected Schottky barrier diodes.
